(19) United States
(12) Patent Application Publication
(10) Pub. No.: US 2007/0127223 A1
(43) Pub. Date: Jun. 7, 2007

(54) PORTABLE STORAGE DEVICE

(75) Inventor: Takeshi Mitsuhashi, Yokohama-shi (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: Kabushiki Kaisha Toshiba, Tokyo (JP)

(21) Appl. No.: 11/563,860

(22) Filed: Nov. 28, 2006

(30) Foreign Application Priority Data
Dec. 2, 2005 (JP) 2005-348989

(51) Int. Cl. H05K 5/00

(52) U.S. Cl. 361/752

(57) ABSTRACT

A portable storage device that is connected to an external device to receive and output a signal, has a cover case that has an opening in a front surface thereof and a slit penetrating a wall thereof, a potential of the inner surface of the cover case being kept at the ground potential by connecting to the external device; a circuit board held in said cover case; a connector terminal for connection to said external device that is connected to a front part of said circuit board and disposed to be exposed through the opening of said cover case; a semiconductor memory for storing data that is mounted on said circuit board and connected to said connector terminal; and a controller mounted on said circuit board for controlling said semiconductor memory.

### CROSS-REFERENCE TO RELATED APPLICATIONS

This application is based upon and claims the benefit of priority from the prior Japanese Patent Application No. 2005-348989, filed on Dec. 2, 2005, the entire contents of which are incorporated herein by reference.

### BACKGROUND OF THE INVENTION

1. Field of the Invention

The present invention relates to a portable storage device that is used by connecting to an external device.

2. Background Art

Portable storage devices incorporating a semiconductor memory chip are now widely used as data storage media for digital devices, such as digital video cameras, cellular phones and portable music players. Such a portable storage device is plugged into a socket on an external digital device before the portable storage device can access the internal circuit of the digital device or data can be written to or read from the portable storage device.

For example, an existing portable storage device has a substantially rectangular cover case having an opening in the front surface thereof, a substantially rectangular circuit board held in the cover case, a connector terminal for connection to an external device connected to a front part of the circuit board and disposed to be exposed through the cover case, a semiconductor memory for storing desired data mounted on the circuit board and connected to the connector terminal, and a controller mounted on the circuit board for controlling the semiconductor memory.

The arrangement according to the prior art described above is highly resistant to external electro-static discharge (ESD) because the internal components are sealed in the cover case. However, when the connector terminal is connected to an electrode of an external terminal and data transfer is carried out, the heat generated by the semiconductor memory, the controller and the like is hard to dissipate to the outside of the cover case and thus can cause a problem of unstable operation of the electronic circuits.

In addition, the heat generated by the semiconductor memory, the controller and the like can cause a thermal stress in the mounted components, which causes degradation in mechanical strength of the components, thereby causing a problem that the life of the product is shortened.

For example, a prior-art heat dissipation arrangement for electronic devices has a hollow heatsink that is disposed in a case and dissipates the heat generated by and transferred from the components in the case and an air flow conduit that extends from one end to the other end of the case through the heatsink (see Japanese Patent Laid-Open No. 11-233977, for example).

However, the prior art described above does not take the electro-static discharge into account. Therefore, if the prior art is applied to a portable storage device, there can arise a problem that an electronic component, such as the semiconductor memory and the controller, malfunctions because of external electro-static discharge introduced through the air flow conduit provided in the cover case.

### SUMMARY OF THE INVENTION

According one aspect of the present invention, there is provided: a portable storage device that is connected to an external device to receive and output a signal, comprising a cover case that has an opening in a front surface thereof and a slit penetrating a wall thereof, a potential of the inner surface of the cover case being kept at the ground potential by connecting to the external device; a circuit board held in said cover case; a connector terminal for connection to said external device that is connected to a front part of said circuit board and disposed to be exposed through the opening of said cover case; a semiconductor memory for storing data that is mounted on said circuit board and connected to said connector terminal; and a controller mounted on said circuit board for controlling said semiconductor memory.

### BRIEF DESCRIPTION OF THE DRAWINGS

FIG. 1 is a top view showing essential parts of a portable storage device according to an embodiment 1 of the present invention;

FIG. 2 is a cross-sectional view of the portable storage device shown in FIG. 1 taken along the line A-A;

FIG. 3 is a cross sectional view showing essential parts of a portable storage device according to an embodiment 2 of the present invention, which is an aspect of the present invention;

FIG. 4 is a top view showing essential parts of a portable storage device according to an embodiment 3 of the present invention, which is an aspect of the present invention;

FIG. 5 is a cross-sectional view of the portable storage device shown in FIG. 4 taken along the line B-B;

FIG. 6 is a side view showing essential parts of a portable storage device according to an embodiment 4 of the present invention, which is an aspect of the present invention; and

FIG. 7 is a cross-sectional view of the portable storage device shown in FIG. 6 taken along the line C-C.

### DETAILED DESCRIPTION

In the following, portable storage devices according to embodiments of the present invention, which are implemented as a USB memory, for example, will be described with reference to the drawings. The present invention can be equally applied to other portable storage devices serving as a storage medium.

### Embodiment 1

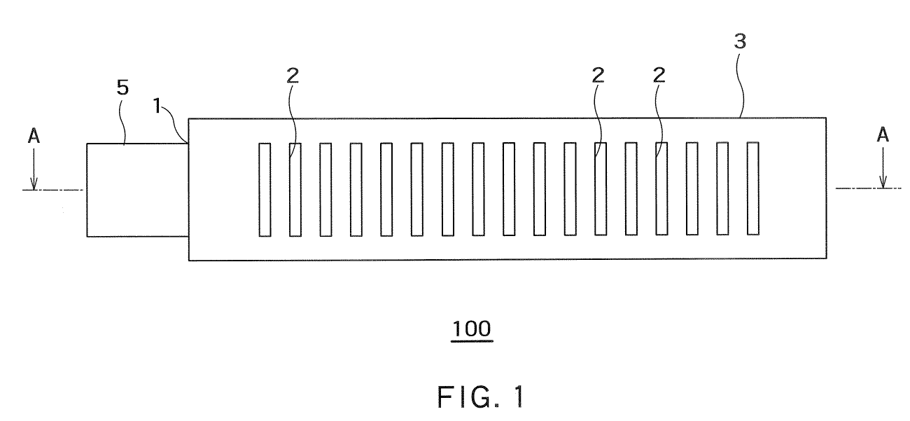

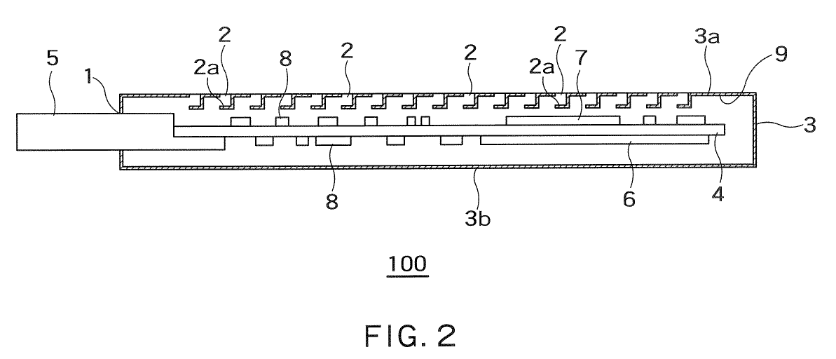

FIG. 1 is a top view showing essential parts of a portable storage device according to an embodiment 1 of the present invention. FIG. 2 is a cross-sectional view of the portable storage device shown in FIG. 1 taken along the line A-A.

As shown in FIGS. 1 and 2, a portable storage device 100 that is to be connected to an external device (not shown) to receive/output signals has a cover case 3 that has a substantially rectangular profile and has an opening 1 formed in the front surface thereof and slits 2 penetrating through a wall thereof, and the potential of the inner surface of the cover case 3 is kept at the ground potential by connecting to the external device.

In addition, the portable storage device 100 has a substantially rectangular circuit board 4 that has circuit wiring mounted thereon and is held in the cover case 3, a connector terminal 5 for connection to an external device that is connected to a front part of the circuit board 4 and disposed to be exposed through the opening 1 in the cover case 3, a semiconductor memory 6 for storing desired data mounted on the circuit board 4 and connected to the connector terminal 5 via the circuit wiring, a controller 7 for controlling the semiconductor memory 6 mounted on the circuit board 4 and connected to the connector terminal 5 via the circuit wiring and a passive element 8 mounted on the circuit board 4, such as a resistor and a capacitor.

The circuit board 4 is made of a resin, such as epoxy.

In the case where a USB memory is used, a USB connector complying with the USB interface is selected as the connector terminal 5. The connector terminal 5 has to be connected to an external device before the connector terminal 5 can be connected to the ground potential.

The semiconductor memory 6 may be a non-volatile memory, such as an NAND flash memory and an NOR flash memory.

The controller 7 controls the semiconductor memory 6 to store and read out desired data and to receive and output a desired signal via the connector terminal, in response to the signal from the external device.

In this embodiment, the cover case 3 is composed of an upper case housing 3a and a lower case housing 3b formed by shaping a material, such as polycarbonate, in a mold. The upper case housing 3a and the lower case housing 3b are sealed together by ultrasonic welding or fitting. The cover case 3 electrically and mechanically protects the semiconductor memory 6, the controller 7 and the passive element 8 from the outside environment.

The slits 2 of the cover case 3 for enhancing heat dissipation are formed in the upper case housing 3a during molding of the upper case housing 3a, for example. For example, when the connector terminal 5 is connected to an external device and data transfer is carried out, the heat generated by the semiconductor memory 6, the controller 7 and the passive element 8 is dissipated to the outside of the cover case 3 through the slits 2. In particular, since slits 2 are disposed above the controller 7, the efficiency of cooling of the controller 7, which generates much heat, can be enhanced.

In the case where the cover case 3 is made of a non-conductive material, such as a non-conductive resin, a conductive coating 9 is formed on the inner surface of the cover case 3 and is connected to the ground potential. Specifically, the coating 9 of a highly conductive material, such as a chromium plating, is formed on the inner surface of the upper case housing 3a having the slits 2 and is connected to a grounding wire of the circuit wiring or to the connector terminal 5 on the circuit board 4.

Thus, static electricity flows from the outer part of the cover case 3 to the ground through the inner surface of the cover case 3, so that discharge of the static electricity to the controller 7 and the passive element 8 on the circuit board 4 can be suppressed.

Even if the semiconductor memory 6 is mounted on the upper surface of the circuit board 4, the electro-static discharge can be equally suppressed.

In addition, the cover case 3 has conductive shielding plates 2a for preventing electro-static discharge between the slits 2 and the controller 7, passive element 8. The shielding plates 2a can shield the controller 7 and the passive element 8 from electro-static discharge which enters from the outside of an upper case 3a through the slits 2.

The shielding plates 2a are made of a conductive material or have a conductive coating on the surface thereof and are electrically connected to the inner surface of the cover case 3. Thus, the static electricity applied to the shielding plates 2a via the slits 2 can be made to flow to the ground through the cover case 3.

As described above, the portable storage device according to this embodiment makes the static electricity applied through the slits flow to the ground through the inner surface of the cover case and dissipates the heat generated by the semiconductor memory, the controller and the passive element to the outside of the cover case through the slits when the connector terminal is connected to the external device, and the portable storage device operates. Therefore, the effect of the electrostatic discharge from the outside and the effect of the thermal stress can be reduced.

In the description of this embodiment, the controller 7 is disposed on the upper surface of the circuit board 4, and the semiconductor memory 6 is disposed on the lower surface of the circuit board 4. However, the controller 7 may be disposed on the lower surface of the circuit board 4, and the semiconductor memory 6 may be disposed on the upper surface of the circuit board 4. Furthermore, both the semiconductor memory 6 and the controller 7 may be disposed on the upper surface of the circuit board 4.

### Embodiment 2

According to the embodiment 1 described above, the slits are formed in the upper wall of the cover case. However, according to this embodiment described below, slits are formed in both the upper and lower walls of the cover case.

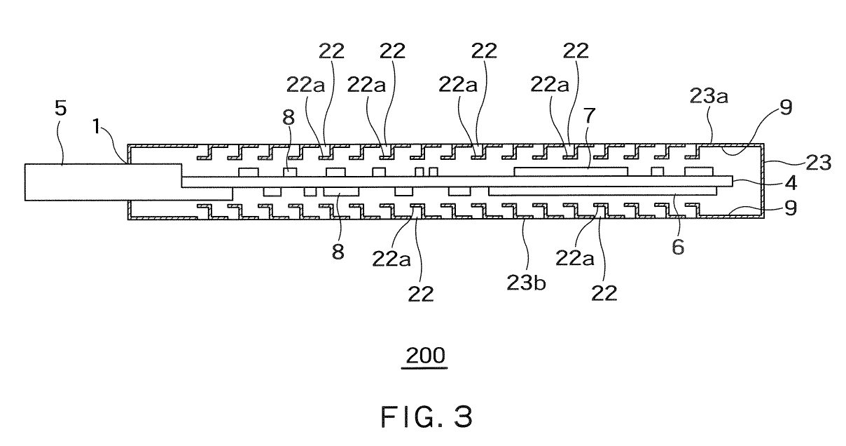

FIG. 3 is a cross sectional view showing essential parts of a portable storage device 200 according to an embodiment 2 of the present invention, which is an aspect of the present invention. In this drawing, the same reference numerals as those used in the embodiment 1 denote the same parts as those according to the embodiment 1.

As shown in FIG. 3, a cover case 23 is composed of an upper case housing 23a and a lower case housing 23b formed by shaping a material, such as polycarbonate, in a mold.

The upper case housing 23a and the lower case housing 23b have slits 22 penetrating walls thereof. The upper case housing 23a and the lower case housing 23b are sealed together by ultrasonic welding or fitting.

In addition, the upper case housing 23a and the lower case housing 23b have conductive shielding plates 22a for preventing electro-static discharge between the slits 22 and a semiconductor memory 6, a controller 7 and a passive element 8.

The slits 22 of the cover case 23 for enhancing heat dissipation are formed in the upper case housing 23a and the lower case housing 23b during molding of the upper case housing 23a and the lower case housing 23b, for example. For example, when a connector terminal 5 is connected to an external device and data transfer is carried out, the heat generated by the semiconductor memory 6, the controller 7 and the passive element 8 is dissipated to the outside of the cover case 23 through the slits 22. In particular, since slits 22 are disposed above the semiconductor memory 6 and the controller 7, the efficiency of cooling of the semiconductor memory 6 and the controller 7, which generate much heat, can be enhanced.

As in the embodiment 1, in the case where the cover case 23 is made of a resin or the like, a conductive coating 9 is formed on the inner surface of the cover case 23 and is connected to the ground potential.

Thus, static electricity flows from the outer part of the cover case 23 to the ground through the inner surface of the slits 22 and the cover case 23, so that discharge of the static electricity to the semiconductor memory 6, the controller 7 and the passive element 8 on the circuit board 4 can be suppressed.

In addition, as in the embodiment 1, the shielding plates 22a can shield the semiconductor memory 6, the controller 7 and the passive element 8 from the electro-static discharge and make the static electricity flow to the ground through the cover case 23.

As described above, the portable storage device according to this embodiment has slits formed in the upper and lower walls of the cover case and dissipates the heat generated by the semiconductor memory, the controller and the passive element from the upper and lower surfaces of the cover case through the slits. Thus, the heat dissipation is enhanced, and the effect of thermal stress can be further reduced.

### Embodiment 3

According to the embodiments 1 and 2 described above, the slits are formed directly in the upper case housing or lower case housing of the cover case. However, according to this embodiment described below, in order to enhance the heat dissipation, a heat dissipation plate having slits is provided to a part of the wall of the cover case.

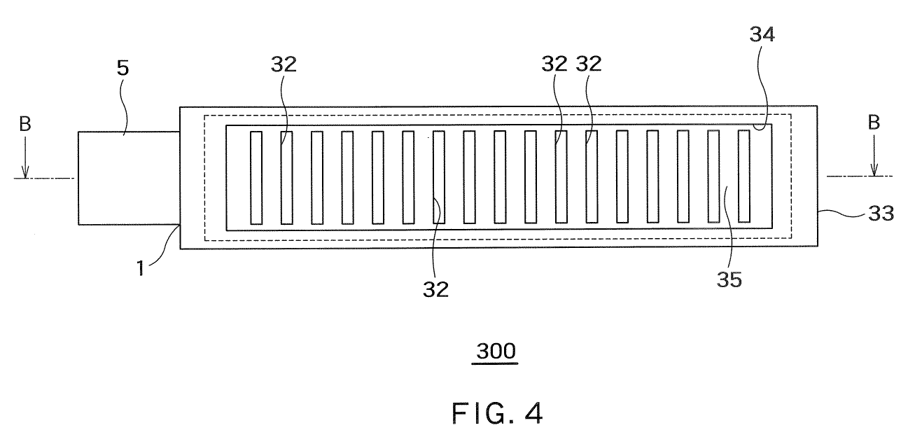

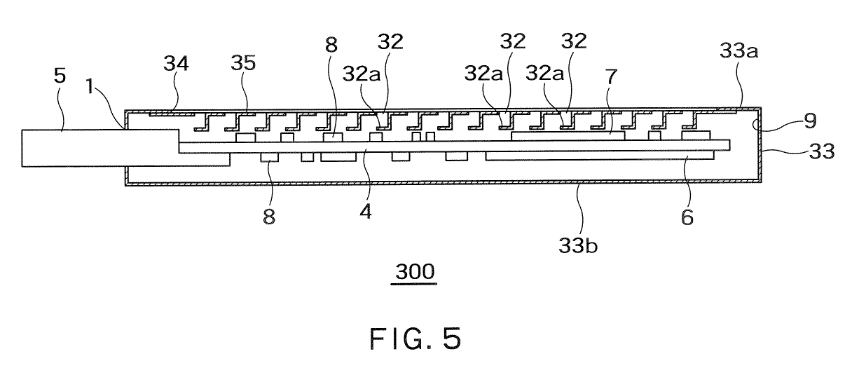

FIG. 4 is a top view showing essential parts of a portable storage device 300 according to an embodiment 3 of the present invention, which is an aspect of the present invention. FIG. 5 is a cross-sectional view of the portable storage device shown in FIG. 4 taken along the line B-B. In the drawings, the same reference numerals as those used in the embodiment 1 denote the same parts as those according to the embodiment 1.

As shown in FIGS. 4 and 5, a cover case 33 is composed of an upper case housing 33a and a lower case housing 33b formed by shaping a material, such as polycarbonate, in a mold. The upper case housing 33a has an opening 34 in the upper wall thereof. A heat dissipation plate 35 having slits 32 is disposed to be exposed through the opening 34. The heat dissipation plate 35 has conductive shielding plates 32a similar to those in the embodiments 1 and 2 for preventing electro-static discharge between the slits 32 and a controller 7, a passive element 8. The perimeter of the upper surface of the heat dissipation plate 35 and the inner surface of the upper case housing 33a are fixed to each other by an adhesive.

For example, the heat dissipation plate 35 is formed by molding an alloy having higher heat conductivity than the material of the cover case 33 or a conductive ceramic material or the like. Accordingly, the heat dissipation to the outside of the cover case can be enhanced.

As described above, the portable storage device according to this embodiment has a heat dissipation plate having slits attached to the wall of the cover case. Thus, compared with the embodiment 1, the heat dissipation can be enhanced, and the effect of thermal stress can be further reduced.

Even if a semiconductor memory 6 is mounted on the upper surface of the circuit board 4, the heat dissipation can be enhanced while equally suppressing the electro-static discharge.

In the description of this embodiment, the heat dissipation plate is attached to the upper wall of the cover case. However, heat dissipation plates may be attached to the upper and lower walls of the cover cases to further enhance the heat dissipation.

### Embodiment 4

According to the embodiments 1 and 2 described above, the slits are formed in the upper wall and/or the lower wall of the cover case. However, according to this embodiment described below, slits are formed in side walls of the cover case.

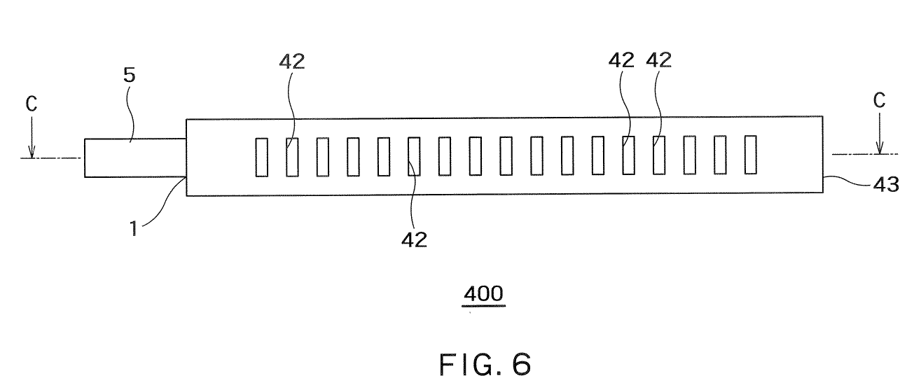

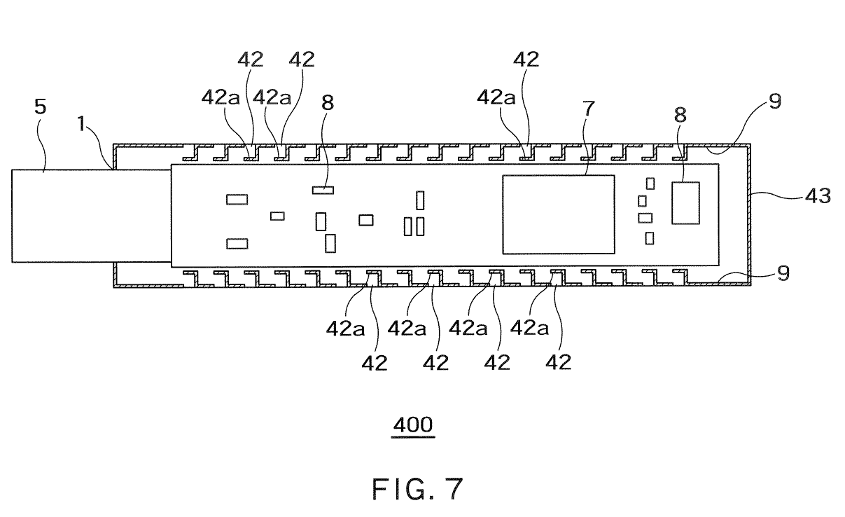

FIG. 6 is a side view showing essential parts of a portable storage device according to an embodiment 4 of the present invention, which is an aspect of the present invention. FIG. 7 is a cross-sectional view of the portable storage device shown in FIG. 6 taken along the line C-C. In the drawings, the same reference numerals as those used in the embodiment 1 denote the same parts as those according to the embodiment 1.

As shown in FIGS. 6 and 7, a cover case 43 has slits 42 penetrating through side walls thereof. In addition, on the side walls of the cover case 43, conductive shielding plates 42a are disposed to prevent electro-static discharge between the slits 42 and a semiconductor memory 6, a controller 7 and a passive element 8.

Thus, for example, when a connector terminal 5 is connected to the external device and data transfer is carried out, the heat generated by the semiconductor memory 6, the controller 7 and the passive element 8 is dissipated to the outside of the cover case 43 through the slits 42.

As in the embodiment 1, in the case where the cover case 43 is made of a resin or the like, a conductive coating 9 is formed on the inner surface of the cover case 43 and is connected to the ground potential.

Thus, static electricity flows from the outer part of the cover case 43 to the ground through the slits 42 and the inner surface of the cover case 43, so that discharge of the static electricity to the semiconductor memory 6, the controller 7 and the passive element 8 on the circuit board 4 can be suppressed.

In addition, as in the embodiment 1, the shielding plates 42a can shield the semiconductor memory 6, the controller 7 and the passive element 8 from the electro-static discharge and make the static electricity flow to the ground through the cover case 43.

If slits are further formed in the upper and lower walls of the cover case 43 as in the embodiments 1 and 2, the heat dissipation can be further enhanced.

As described above, the portable storage device according to this embodiment has slits formed in the side walls of the cover case and dissipates the heat generated by the semiconductor memory, the controller and the passive element from the right and left sides of the cover case through the slits formed in the right and left side surfaces. Thus, the effect of thermal stress can be further reduced.

According to the embodiments described above, the cover case has the upper case housing and the lower case housing. However, the same advantages and effects can be achieved even if the both upper and lower case housings are formed as a single cover case.

In addition, according to the embodiments described above, the cover case is made of polycarbonate or the like. However, the cover case may be made of a conductive material, such as metal. In that case, there is no need to form a conductive coating on the inner surface of the cover case.

In addition, according to the embodiments described above, the cover case and the circuit board are rectangular. However, the cover case and the circuit board can have other shapes.

What is claimed is:

1. A portable storage device that is connected to an external device to receive and output a signal, comprising:
a cover case that has an opening in a front surface thereof and a slit penetrating a wall thereof, a potential of the inner surface of the cover case being kept at the ground potential by connecting to the external device;
a circuit board held in said cover case;
a connector terminal for connection to said external device that is connected to a front part of said circuit board and disposed to be exposed through the opening of said cover case;
a semiconductor memory for storing data that is mounted on said circuit board and connected to said connector terminal; and
a controller mounted on said circuit board for controlling said semiconductor memory.

2. The portable storage device according to claim 1, wherein a conductive coating is formed on the inner surface of said cover case and is connected to the ground potential.

3. The portable storage device according to claim 2, wherein said cover case has a conductive shielding plate for preventing electro-static discharge between said slit and said semiconductor memory or said controller.

4. The portable storage device according to claim 3, wherein said cover case has a heat dissipation plate having a slit attached to at least a part of the wall thereof.

5. The portable storage device according to claim 4, wherein said conductive coating is connected to said connector terminal or a grounding wire on said circuit board.

6. The portable storage device according to claim 1, wherein said cover case has a conductive shielding plate for preventing electro-static discharge between said slit and said semiconductor memory or said controller.

7. The portable storage device according to claim 1, wherein said cover case has a heat dissipation plate having a slit attached to at least a part of the wall thereof.

8. The portable storage device according to claim 2, wherein said conductive coating is connected to said connector terminal or a grounding wire on said circuit board.

9. The portable storage device according to claim 3, wherein said conductive coating is connected to said connector terminal or a grounding wire on said circuit board.

10. The portable storage device according to claim 1, wherein the cover case is made of a conductive material.

11. The portable storage device according to claim 2, wherein the cover case is made of a non-conductive resin.
